(19) United States
(12) Patent Application Publication
(10) Pub. No.: US 2014/0041694 A1
(43) Pub. Date: Feb. 13, 2014

(54) CLEANING SOLUTION PRODUCING APPARATUS, CLEANING SOLUTION PRODUCING METHOD, AND SUBSTRATE CLEANING APPARATUS

(71) Applicant: Shibaura Mechatronics Corporation, Yokohama-shi (JP)

(72) Inventors: Kunihiro MIYAZAKI, Minato-ku (JP); Konosuke Hayashi, Yokohama-shi (JP)

(73) Assignee: Shibaura Mechatronics Corporation, Yokohama-shi (JP)

(21) Appl. No.: 13/961,216

(22) Filed: Aug. 7, 2013

(30) Foreign Application Priority Data
Aug. 9, 2012 (JP) 2012-177122
Jun. 6, 2013 (JP) 2013-119525

(51) Int. Cl. H01L 21/67

(52) U.S. Cl. CPC H01L 21/6704
USPC 134/102.2; 422/198; 422/224; 422/225; 422/110; 510/375

(57) ABSTRACT

An cleaning solution producing apparatus according to an embodiment includes: a mixing unit configured to produce a liquid mixture by mixing a hydrogen peroxide solution into an acidic or alkaline liquid, and to raise the pressure of the produced liquid mixture by use of an oxygen gas produced through the decomposition of the hydrogen peroxide solution, or by use of vapor produced by heat of the reaction; and a bubble producing unit configured to produce multiple fine bubbles in the liquid mixture by releasing the pressure of the liquid mixture which is raised by the mixing unit.

### CROSS-REFERENCE TO THE RELATED APPLICATION

This application is based on and claims the benefit of priority from Japanese Patent Applications No. 2012-177122, filed on Aug. 9, 2012 and No. 2013-119525, filed on Jun. 6, 2013; the entire contents of which are incorporated herein by reference.

### FIELD

Embodiments relate to a cleaning solution producing apparatus, a cleaning solution producing method, and a substrate cleaning apparatus.

### BACKGROUND

A substrate cleaning apparatus performs cleaning processes (for example, resist stripping, particle removal and metal removal) on a substrate by supplying a cleaning solution to the substrate. Substrate cleaning apparatuses are widely in use, for example, for manufacturing processes for semiconductor devices, liquid crystal display apparatuses, and the like. In the manufacturing process of semiconductor devices, a technique for stripping resist applied to semiconductor substrates is to remove resist by use of a mixture of sulfuric acid and a hydrogen peroxide solution, that is, an SPM (Sulfuric acid and Hydrogen Peroxide Mixture) treatment solution.

There are several methods of cleaning a single semiconductor substrate by using the SPM treatment solution. For example, sulfuric acid and a hydrogen peroxide solution are mixed on a semiconductor substrate in one method, whereas sulfuric acid and a hydrogen peroxide solution are mixed first, and then the mixture is discharged onto a semiconductor substrate in another method. After cleaned with the SPM treatment solution, the semiconductor substrate is rinsed with water and dried, and is thereafter conveyed to a subsequent manufacturing step. Otherwise, after rinsed with water, the semiconductor substrate is cleaned with another cleaning chemical solution once again, is rinsed with water and dried, and is thereafter conveyed to the subsequent manufacturing step.

Nevertheless, in the case where the semiconductor substrate is only cleaned with the above-mentioned SPM treatment solution, the cleaning is insufficient. For this reason, the cleaning performance is required to be enhanced. For example, when ions are implanted into the surface of the semiconductor substrate, the surface of the resist film is hardened (changes in nature) after the ion implantation. It is difficult to remove the hardened resist by use of the above-mentioned SPM treatment solution, and residues of the resist accordingly remain on the semiconductor substrate.

### BRIEF DESCRIPTION OF THE DRAWINGS

FIG. 1 is a diagram showing a schematic configuration of a substrate cleaning apparatus of an embodiment.

FIG. 2 is a diagram showing a schematic configuration of a mixing unit and a bubble producing unit included in the substrate cleaning apparatus shown in FIG. 1.

FIG. 3 is a flowchart showing the flow of a substrate cleaning process (including a cleaning solution producing step) which is carried out by the substrate cleaning apparatus shown in FIG. 1.

### DETAILED DESCRIPTION

In an embodiment, a cleaning solution producing apparatus includes: a mixing unit configured to produce a liquid mixture by mixing a hydrogen peroxide solution into an acidic or alkaline liquid, and to raise the pressure of the produced liquid mixture by use of an oxygen gas produced through the decomposition of the hydrogen peroxide solution, or by use of vapor produced by heat of the reaction; and a bubble producing unit configured to produce multiple fine bubbles in the liquid mixture by releasing the pressure of the liquid mixture which is raised by the mixing unit.

In another embodiment, a cleaning solution producing method includes the steps of: producing a liquid mixture by mixing a hydrogen peroxide solution into an acidic or alkaline liquid, and raising the pressure of the produced liquid mixture by use of an oxygen gas produced through the decomposition of the hydrogen peroxide solution, or by use of vapor produced by heat of the reaction; and producing multiple fine bubbles in the liquid mixture by releasing the raised pressure of the liquid mixture.

In yet another embodiment, a substrate cleaning apparatus includes: a mixing unit configured to produce a liquid mixture by mixing a hydrogen peroxide solution into an acidic or alkaline liquid, and to raise the pressure of the produced liquid mixture by use of an oxygen gas produced through the decomposition of the hydrogen peroxide solution, or by use of vapor produced by heat of the reaction; a bubble producing unit configured to produce multiple fine bubbles in the liquid mixture by releasing the pressure of the liquid mixture which is raised by the mixing unit; and a cleaning section configured to clean a substrate by use of the liquid mixture containing the multiple fine bubbles which are produced by the bubble producing unit.

In still another embodiment, a substrate cleaning method includes the steps of: producing a liquid mixture by mixing a hydrogen peroxide solution into an acidic or alkaline liquid, and raising the pressure of the produced liquid mixture by use of an oxygen gas produced through the decomposition of the hydrogen peroxide solution, or by use of vapor produced by heat of the reaction; producing multiple fine bubbles in the liquid mixture by releasing the raised pressure of the liquid mixture; and cleaning a substrate by use of the liquid mixture containing the multiple produced fine bubbles.

Descriptions will be provided for an embodiment while referring to the drawings.

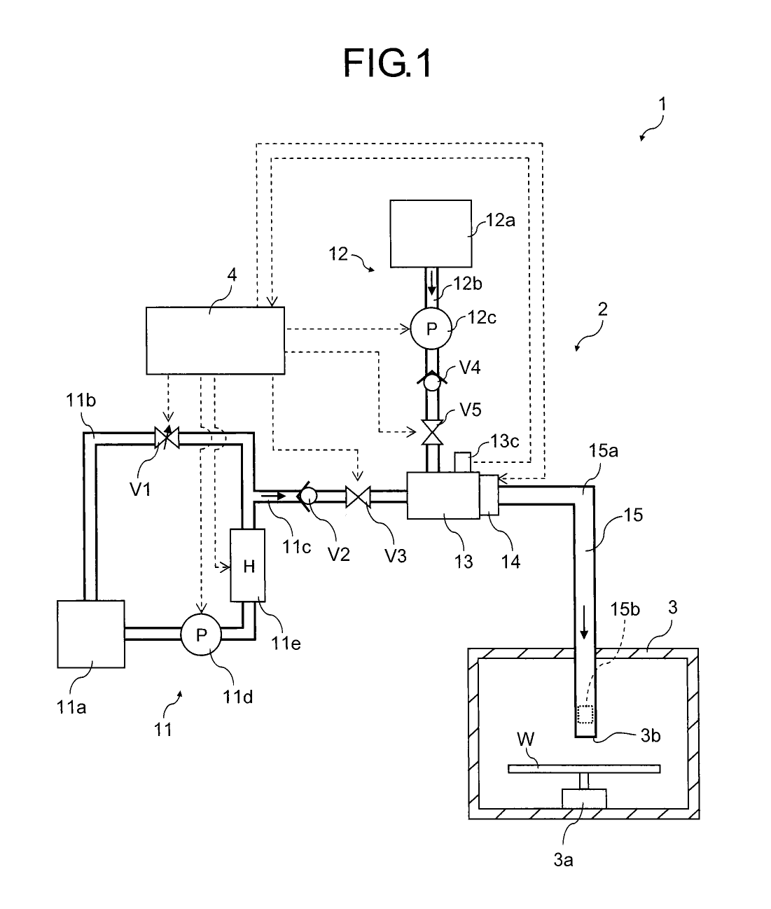

As shown in FIG. 1, a substrate cleaning apparatus 1 of the embodiment includes: a cleaning solution producing device (apparatus) 2 configured to produce a cleaning solution; a cleaning section 3 configured to clean a substrate W by use of the cleaning solution produced by the cleaning solution producing device 2; and a controller 4 configured to control the various components.

The cleaning solution producing device 2 includes: a first supply unit 11 configured to heat and supply sulfuric acid which is an example of the acidic liquid; a second supply unit 12 configured to supply a hydrogen peroxide solution; a mixing unit 13 configured to mix the sulfuric acid supplied from the first supply unit 11 and the hydrogen peroxide solution supplied from the second supply unit 12; a bubble producing unit 14 configured to produce multiple fine bubbles in the liquid mixture produced by the mixing unit 13; and a discharge pipe 15 configured to discharge the liquid mixture containing the multiple fine bubbles which are produced by the bubble producing unit 14.

The first supply unit 11 includes: a first reservoir 11a configured to store the sulfuric acid, such as a tank; a circulation pipe 11b connected to the first reservoir 11a; a first supply pipe 11c configured to supply the sulfuric acid from the circulation pipe 11b to the mixing unit 13; a first pressure feeder 11d configured to pressure-feed the sulfuric acid to the mixing unit 13; and a heating unit 11e configured to heat the sulfuric acid flowing in the circulation pipe 11b.

The circulation pipe 11b is connected in such a way that the sulfuric acid in the first reservoir 11a returns to the first reservoir 11a after flowing in the circulation pipe 11b. A flow rate adjustment valve V1 configured to adjust the flow rate of the sulfuric acid flowing in the circulation pipe 11b is provided in the middle of the circulation pipe 11b. The flow rate adjustment valve V1 is electrically connected to the controller 4, and adjusts the flow rate of the sulfuric acid flowing in the circulation pipe 11b in accordance with the control by the controller 4. For example, the flow rate of the sulfuric acid flowing in the circulation pipe 11b is adjusted by the flow rate adjustment valve V1 in order to be kept constant.

The first supply pipe 11c is that which connects the circulation pipe 11b and the mixing unit 13 together. The first supply pipe 11c is provided with: a check valve V2 configured to check the sulfuric acid from flowing in the reverse direction by making the sulfuric acid always flow in one direction; and an on-off valve V3 configured to open and close the first supply pipe 11c. The on-off valve V3 is electrically connected to the controller 4, and controls the supply of the sulfuric acid to the mixing unit 13 by opening and closing the first supply pipe 11c in accordance with the control by the controller 4.

The first pressure feeder 11d is electrically connected to the controller 4, circulates the sulfuric acid in the circulation pipe 11b by applying pressure to the sulfuric acid in accordance with the control by the controller 4, and pressure-feeds the sulfuric acid to the mixing unit 13 through the first supply pipe 11c. A pump, for example, may be used as the first pressure feeder 11d.

The heating unit 11e is provided in the middle of the circulation pipe 11b and is capable of heating the sulfuric acid flowing in the circulation pipe 11b. The heating unit 11e is electrically connected to the controller 4, and heats the sulfuric acid flowing in the circulation pipe 11b in accordance with the control by the controller 4. A heater, for example, may be used as the heating unit 11e. The heater temperature is in a range of 60 degrees centigrade to 160 degrees centigrade (in a range not lower than 60 degrees centigrade but not higher than 160 degrees centigrade), and is set at 120 degrees centigrade, for example. The temperature of the sulfuric acid in high-temperature circulation is accordingly set at 120 degrees centigrade. As long as the temperature is kept in this range, the mixture of the sulfuric acid heated at the high temperature and the hydrogen peroxide solution at normal temperature can be used in the cleaning process by additionally employing only the heat of reaction which is produced by the mixture (the solution temperature preferable for the cleaning process is in a range of 140 degrees centigrade to 180 degrees centigrade). This enables the process to be efficiently performed without damaging the substrate W.

The second supply unit 12 includes: a second reservoir 12a configured to store the hydrogen peroxide solution, such as a buffer tank; a second supply pipe 12b configured to supply the hydrogen peroxide solution from the second reservoir 12a to the mixing unit 13; and a second pressure feeder 12c configured to pressure-feed the hydrogen peroxide solution to the mixing unit 13.

The second supply pipe 12b is that which connects the second reservoir 12 and the mixing unit 13 together. The second supply pipe 12b is provided with: a check valve V4 configured to check the hydrogen peroxide solution from flowing in the reverse direction by making the hydrogen peroxide solution always flow in one direction; and an on-off valve V5 configured to open and close the second supply pipe 12b. The on-off valve V5 is electrically connected to the controller 4, opens and closes the second supply pipe 12b in accordance with the control by the controller 4, and controls the supply of the hydrogen peroxide solution to the mixing unit 13.

The second pressure feeder 12c is electrically connected to the controller 4, and pressure-feeds the hydrogen peroxide solution to the mixing unit 13 through the second supply pipe 12b by applying pressure to the hydrogen peroxide solution in accordance with the control by the controller 4. A pump, for example, may be used as the second pressure feeder 12c.

The mixing unit 13 has a sealed structure. The mixing unit 13 produces a liquid mixture (SPM: a Sulfuric acid and Hydrogen Peroxide Mixture) by mixing the sulfuric acid at high temperature (for example, at 120 degrees centigrade) supplied from the first supply pipe 11c and the hydrogen peroxide solution at normal temperature which is supplied from the second supply pipe 12b. Furthermore, the mixing unit 13 is a unit configured to raise the pressure of the produced liquid mixture by use of an oxygen gas produced through the decomposition of the hydrogen peroxide solution, or by use of vapor produced by the heat of the reaction.

The mixing unit 13 is made from a high-temperature proof resin such as a fluororesin, or a ceramic material such as SiC or Si₃N₄, because the temperature of the liquid mixture becomes higher. In a case where the mixing unit 13 is made from the ceramic material, the mixing unit 13 can easily withstand a high temperature, for example in a range of 120 degrees centigrade to 160 degrees centigrade, because the ceramic material is good at heat resisting property.

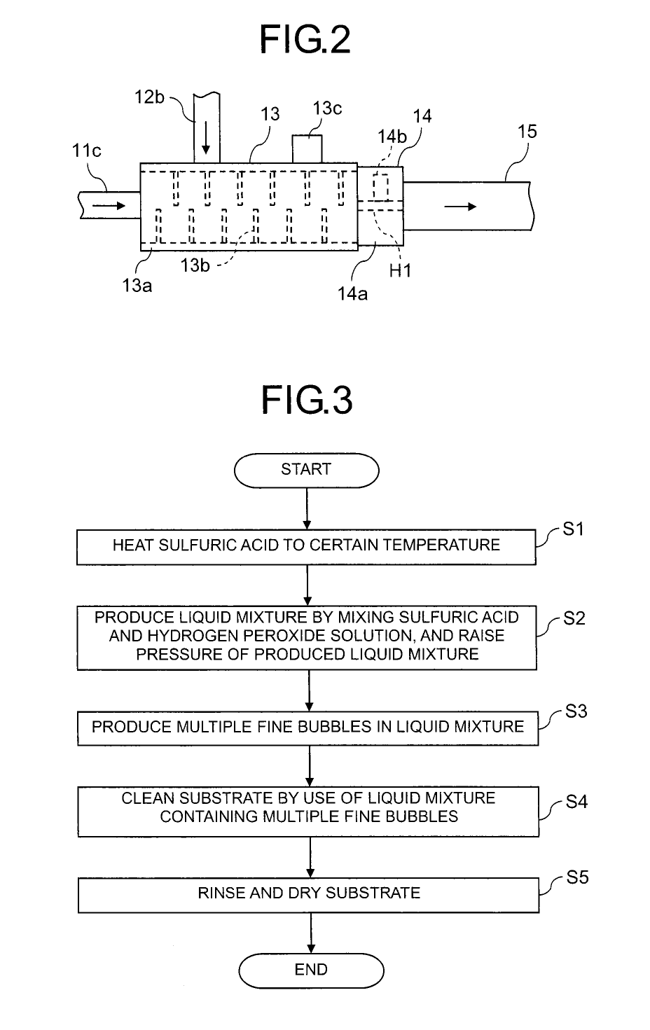

As shown in FIG. 2, the mixing unit 13 thus made includes: a mixing pipe 13a configured to mix the sulfuric acid at the high temperature supplied from the first supply pipe 11c and the hydrogen peroxide solution at normal temperature supplied from the second supply pipe 12b; and an agitation structure 13b configured to agitate the sulfuric acid and the hydrogen peroxide solution in the mixing pipe 13a.

The mixing pipe 13a is a pipe configured to mix the pressure-fed sulfuric acid at the high temperature and the pressure-fed hydrogen peroxide solution at normal temperature.

The mixing pipe 13a is formed to have a large volume, that is to say, to have an inner diameter (size) larger than the inner diameter of the first supply pipe 11c and the inner diameter of the second supply pipe 12b. Thereby, the flow speed of the liquid mixture flowing inside the mixing pipe 13a can be made slower than in a case where the inner diameter of the mixing pipe 13a is equal to or smaller than that of each of the first supply pipe 11c and the second supply pipe 12b. As the flow speed becomes lower, the time for the reaction between the sulfuric acid and the hydrogen peroxide solution becomes longer. For this reason, even though the length of the pipe is short, it is possible to make the sulfuric acid and the hydrogen peroxide solution sufficiently react on each other. Incidentally, it is not essential that the pipe diameter of the mixing pipe 13a be larger. If a length of time can be secured for the sufficient reaction between the sulfuric acid and the hydrogen peroxide solution, the pipe diameter of the mixing pipe 13a does not have to be made larger. For example, the mixing pipe 13a may be formed with a pipe diameter equal to that of the first supply pipe 11c and that of the second supply pipe 12b, and with a sufficiently long length.

The agitation structure 13b is provided in the inside of the mixing pipe 13a. The agitation structure 13b is capable of agitating the sulfuric acid and the hydrogen peroxide solution, and accelerates the mixing of the sulfuric acid at the high temperature and the hydrogen peroxide solution at normal temperature by agitating them. For example, an agitation structure in which multiple blades making the flow passage spiral are provided to the inner wall of the mixing unit 13 may be used as the agitation structure 13b. Incidentally, the agitation structure 13b does not have to be provided therein if the sulfuric acid and the hydrogen peroxide solution can be mixed sufficiently by use of the mixing pipe 13a alone.

In addition, the mixing unit 13 is provided with a detector 13c configured to detect both the temperature and pressure of the liquid mixture in the inside of the mixing unit 13. The detector 13c is electrically connected to the controller 4, and outputs the detected temperature and pressure to the controller 4. Incidentally, a detector configured to detect either the temperature or pressure of the liquid mixture may be used as the detector 13c instead of the detector configured to detect both the temperature and pressure of the liquid mixture. On the basis of a result of the detection by the detector 13 of this kind, the controller 4 is capable of controlling the temperature setting of the heating unit 11e, and is further capable of controlling the pressure of the first pressure feeder 11d and the pressure of the second pressure feeder 12c.

As shown in FIG. 2, the bubble producing unit 14 includes: an orifice member 14a in which a through-hole H1 is made, the liquid mixture passing through the through-hole H1; and an adjustment mechanism 14b configured to adjust the opening degree of the through-hole H1.

The inner diameter of the through-hole H1 is extremely smaller than that of the pipe 13a of the mixing unit 13 and that of the discharge pipe 15. In other words, the through-hole H1 is made with an inner diameter size which enables the through-hole H1 to produce the multiple fine bubbles. In addition, the adjustment mechanism 14b is electrically connected to the controller 4, and adjusts the opening degree of the through-hole H1 in accordance with the control by the controller 4. Incidentally, an adjustment mechanism configured to change the opening degree of the through-hole H1 by moving a member for closing the through-hole H1 may be used as the adjustment mechanism 14b.

In this respect, using the temperature and pressure detected by the detector 13c, the controller 4 controls the opening degree of the through-hole H1 by use of the adjustment mechanism 14b in order that a desired predetermined number of fine bubbles can be produced stably. For example, in a case where the temperature and pressure detected by the detector 13c are lower than the temperature and pressure needed to obtain the desired number of fine bubbles, which are beforehand obtained by an experiment, the opening degree of the through-hole H1 is controlled to be narrower. This makes it possible to stably obtain the liquid mixture containing the desired number of fine bubbles.

The bubble producing unit 14 is connected to the outflow port of the mixing unit 13, and produces the large number of fine bubbles in the liquid mixture by releasing the pressure of the liquid mixture in the mixing unit 13 while letting the liquid mixture pass through the through-hole H1. In the mixing unit 13, the temperature of the reaction (the heat of neutralization) makes the temperature of the liquid mixture (the solution) become not lower than the temperature of the sulfuric acid before supplied, and the hydrogen peroxide solution is decomposed into water and the oxygen gas. In addition, since the temperature of the liquid mixture exceeds 100 degrees centigrade, part of the water is turned into vapor. For these reasons, the boiling point of the liquid mixture rises immediately before the bubble producing unit 14 because the internal pressure increases due to the gases (the oxygen gas and the vapor) produced in the liquid mixture which is passing through the through-hole H1. Furthermore, while the liquid mixture containing the gases is passing through the through-hole H1 which is a narrow hole, portions of the gasses in the liquid mixture are isolated from one another, and become the fine (minute) bubbles.

It should be noted that instead of the orifice member 14a, for example, a venturi tube or the like may be used as the bubble producing unit 14. Any structure may be used as long as the structure is capable of producing the fine bubbles in the liquid mixture. No specific restriction is imposed on the structure.

In this regard, the fine bubbles are bubbles which are conceptually defined as micro-bubbles (MB), micro-nano-bubbles (MNB), nano-bubbles (NB) and the like. For example, micro-bubbles are bubbles which are 10 micrometers to tens of micrometers in diameter; micro-nano-babbles are bubbles which are hundreds of nanometers to 10 micrometers in diameter; and nano-bubbles are bubbles which are not larger than hundreds of nanometers in diameter.

Let us return to FIG. 1. The discharge pipe 15 is that which is configured to discharge the liquid mixture containing the multiple fine bubbles which are produced by the bubble producing unit 14. An extremity portion of the discharge pipe 15 on a discharging side is provided to the cleaning section 3 with the extremity portion thereof directed toward the top surface of the substrate W. The liquid containing the fine bubbles has a characteristic of increasing the efficiency of cleaning the substrate W. The speed at which the fine bubbles come up to the surface of the liquid is low, and the fine bubbles accordingly stay in the liquid for a longer period of time. For these reason, the fine bubbles have a characteristic in which when the fine bubbles contact foreign matters such as particles existing on the substrate W, the fine bubbles adsorb the foreign matters and remove the foreign matters from the top of the substrate W.

The discharge pipe 15 is formed with an inner diameter (size) larger than that of the first supply pipe 11c and that of the second supply pipe 12b. Thereby, the flow speed at which the liquid mixture flows in the discharge pipe 15 can be made lower than in a case where the inner diameter of the discharge pipe 15 is not larger than that of the first supply pipe 11c and that of the second supply pipe 12b. For this reason, it is possible to reduce damage which the liquid mixture discharged from the discharge pipe 15 will cause on the top surface of the substrate W.

In addition, the discharge pipe 15 has a bent portion 15a, bent at an angle of 90 degrees, in one place. In other words, the discharge pipe 15 has at least one bent portion, which is bent at an angle equal to or larger than 45 degrees, as the bent portion 15a. By this, the flow speed at which the liquid mixture flows in the discharge pipe 15 can be made lower than in a case where the discharge pipe 15 is straight. For this reason, it is possible to reduce damage which the liquid mixture discharged from the discharge pipe 15 will cause on the top surface of the substrate W. Moreover, the fine bubbles can be made to collide against the inner wall of the discharge pipe 15. For this reason, it is possible to make the fine bubbles become much finer by further isolating the fine bubble from one another.

What is more, the discharge pipe 15 has a net member 15b which is configured to decrease the flow speed of the liquid mixture containing the multiple fine bubbles, and concurrently to make the fine bubbles become far finer. The net member 15b is formed in the shape of a mesh, and is provided to the inside of the discharge pipe 15. Thereby, it is possible to decrease the flow speed at which the liquid mixture flows in the discharge pipe 15. For this reason, it is possible to further reduce damage which the liquid mixture discharged from the discharge pipe 15 will cause on the top surface of the substrate W. Furthermore, the fine bubbles in the liquid mixture can be isolated from one another. For this reason, the fine bubbles can be made to become much finer.

It should be noted that although a pipe whose inner diameter (size) is constant is used as the discharge pipe 15, this is not the only choice. A pipe shaped like a rocket nozzle (in a tapered shape) may be used as the discharge pipe 15.

The cleaning section 3 is a cleaning unit configured to remove a resist film from the top surface of the substrate W by use of the liquid mixture containing the large number of fine bubbles. The cleaning section 3 includes: a rotary mechanism 3a configured to turn the substrate W; and a nozzle 3b configured to supply the liquid mixture to the top of the substrate W which is turned by the rotary mechanism 3a. The nozzle 3b is an end portion of the discharge pipe 15. As the cleaning solution, the liquid mixture is discharged from the nozzle 3b. In other words, the cleaning unit 3 removes the resist film from the top surface of the substrate W by supplying the liquid mixture containing the large number of fine bubbles, as the cleaning solution, from the nozzle 3b to the top surface of the turning substrate W. The cleaning solution flowing from the top of the substrate W reaches the bottom surface of the cleaning section 3, and subsequently flows in a drain pipe connected to the bottom surface thereof, and is eventually drained.

In this regard, although the cleaning section configured to remove the resist film from the top surface of the substrate W is used as the cleaning section 3, this is not the only choice. Instead, a cleaning section configured to remove metal from the top surface of the substrate W, and a cleaning section configured to remove particles from the top surface of the substrate W, for example, may be used as the cleaning section 3. In this case, instead of the sulfuric acid (H₂SO₄) for removing a resist film, hydrochloric acid (HCl) for removing metal may be used as the acidic liquid; and ammonium hydroxide (NH₄OH) for removing particles may be used as the alkaline liquid. Incidentally, when hydrochloric acid is used, a liquid mixture between hydrochloric acid and the hydrogen peroxide solution is HPM (a hydrochloric acid and hydrogen peroxide mixture). When ammonium hydroxide is used, a liquid mixture between ammonium hydroxide and the hydrogen peroxide solution is APM (an ammonia and hydrogen peroxide mixture). Moreover, the cleaning section 3 is not limited to the cleaning section configured to process the substrate W while turning it. A cleaning section configured to process the substrate W while transferring it by use of rollers may be used as the cleaning section 3.

The controller 4 includes: a microcomputer configured to centrally control the various components; and a storage unit configured to store process information on the cleaning solution production and the substrate cleaning, as well as various programs. On the basis of the process information and the various programs, the controller 4 performs control in order for the cleaning solution producing device 2 to produce the liquid mixture (SPM: sulfuric acid and hydrogen peroxide mixture) containing the large number of fine bubbles as the cleaning solution, and in order for the cleaning section 3 to clean the substrate W by use of the thus-produced liquid mixture.

Next, descriptions will be provided for the substrate cleaning process (including the cleaning solution producing process for producing the cleaning solution) which is carried out by the substrate cleaning apparatus 1 by referring to FIG. 3.

As shown in FIG. 3, the substrate cleaning process of the embodiment includes the steps of: heating sulfuric acid (step S1); mixing the heated sulfuric acid and a hydrogen peroxide solution at normal temperature (step S2); producing a large number of fine bubbles in the liquid mixture (step S3); cleaning a substrate with the liquid mixture (step S4); and finally rinsing and drying the substrate (step S5).

To put it in detail, the sulfuric acid, which is circulated in the circulation pipe 11b by the first pressure feeder 11d, is heated by the heating unit 11e to a predetermined temperature (for example, 120 degrees centigrade) (in step S1). Through this heating, the temperature of the sulfuric acid circulating in the circulation pipe 11b is kept constant at the predetermined temperature.

Subsequently, once the on-off valve V3 in the first supply pipe 11c and the on-off valve V5 in the second supply pipe 12b are put by the controller 4 into the opened state, the sulfuric acid at the high temperature and the hydrogen peroxide solution at normal temperature are pressure-fed and thus supplied to the mixing unit 13. The supplied sulfuric acid at the high temperature and the supplied hydrogen peroxide solution at normal temperature are mixed by the mixing unit 13 into the liquid mixture. In addition, the pressure of the produced liquid mixture is raised (in step S2).

During this step, in the mixing unit 13, the temperature of the liquid mixture (the solution) becomes not lower than that of the supplied sulfuric acid because of the heat of the reaction (the heat of the neutralization), as well as water and an oxygen gas are produced through the decomposition of the hydrogen peroxide solution. Furthermore, since the temperature of the liquid mixture exceeds 100 degrees centigrade, part of the water is turned into vapor. The oxygen gas produced through the decomposition of the hydrogen peroxide solution or the vapor produced through the boiling raises the pressure of the liquid mixture. In addition, the agitation structure 13b of the mixing unit 13 agitates the sulfuric acid at the high temperature and the hydrogen peroxide solution at normal temperature, and accordingly accelerates their mixing.

Thereafter, once the liquid mixture whose pressure has risen passes through the through-hole H1 of the bubble producing unit 14, the multiple fine bubbles occur in the liquid mixture because of the pressure release (in step S3). During this step, in the bubble producing unit 14, its internal pressure rises since the oxygen gas and the vapor occur in the liquid mixture, and the boiling point of the liquid mixture accordingly rises. Moreover, while the liquid mixture containing the oxygen gas and the vapor is passing through the through-hole H1 which is the narrow hole, portions of the oxygen gas and portions of the vapor in the liquid mixture are isolated from one another, and are turned into the finer bubbles. Incidentally, since the inner diameter of the through-hole H1 is set extremely smaller than that of the pipe 13a of the mixing unit 13, the through-hole H1 contributes to a rise in the pressure of the liquid mixture.

Afterward, the liquid mixture containing the large number of fine bubbles flows in the discharge pipe 15, and is discharged from the nozzle 3b, which is the extremity portion of the discharge pipe 15, to the top surface of the substrate W. Thereby, the liquid mixture removes the resist film from the top surface of the substrate W, and the top surface of the substrate W is thus cleaned (in step S4). During this cleaning, the substrate W is turned in a plane by the rotary mechanism 3a.

After cleaned by the liquid mixture, the substrate W is rinsed and thereafter dried (in step S5), and is conveyed to the subsequent manufacturing process. Incidentally, the drying may be performed by used of: a drying method in which water on the substrate W is shaken off by use of centrifugal force by making the rotary mechanism 3a of the cleaning unit 3 rotate the substrate W; a drying method in which an organic solvent having quick drying properties (for example, IPA: isopropyl alcohol) is applied to the substrate W and subsequently, the organic solvent on the substrate W is shaken off as in the above-mentioned case.

In the above-described substrate cleaning process, the temperature of the liquid mixture rises due to the temperature of reaction (the temperature of neutralization) produced by mixing the sulfuric acid heated at the high temperature and the hydrogen peroxide solution at normal temperature. For this reason, the resist can be removed by employing the thus-raised high temperature and high oxidizing power. In addition, the pressure of the liquid mixture can be raised by use of the oxygen gas produced through the decomposition of the hydrogen peroxide solution or the vapor produced by the boiling, and the temperature of the liquid mixture can be raised further by use of the rise in the boiling point. For this reason, the resist removing performance can be enhanced further. Moreover, after the pressure of the liquid mixture is raised by the oxygen gas produced through the decomposition of the hydrogen peroxide solution or the vapor produced by the boiling, the pressure is released from the liquid mixture while the liquid mixture is passing through the through-hole H1. Thereby, the multiple fine bubbles occur in the liquid mixture. The use of the liquid mixture containing the fine bubbles makes it possible to easily remove residues of the resist and the like, which are carbonized on the substrate W, in cooperation with the bubbles. For this reason, the cleaning performance can be enhanced. What is more, since the oxygen gas produced through the decomposition of the hydrogen peroxide solution or the vapor produced by the boiling is made to pass through the narrow through-hole H1 together with the liquid mixture, portions of the oxygen gas and portions of the vapor in the liquid mixture can be isolated from one another as well. Incidentally, although the sulfuric acid is stable even at the high temperature, the decomposition reaction of the hydrogen peroxide solution is accelerated at the high temperature. For this reason, the temperature of the hydrogen peroxide solution is not raised before the mixing.

Besides, in the mixing unit 13, the flow speed of the liquid mixture decreases since the inner diameter of the mixing pipe 13a is larger than that of the first supply pipe 11c and that of the second supply pipe 12b. Moreover, in the discharge pipe 15, too, the flow speed of the liquid mixture decreases since the inner diameter of the discharge pipe 15 is larger than that of the first supply pipe 11c and that of the second supply pipe 12b. In addition, the flow speed of the liquid mixture further decreases because of the bent portion 15a and the net member 15b of the discharge pipe 15. These make it possible to reduce the flow speed at which the liquid mixture flows in the discharge pipe 15, and accordingly to reduce damage which the liquid mixture discharged from the discharge pipe 15 will cause on the top surface of the substrate W.

What is more, in the bubble producing unit 14, the adjustment mechanism 14b is controlled by the controller 4, and the opening degree of the through-hole H1 is accordingly adjusted. In other words, using the temperature of pressure detected by the detector 13c, the controller 4 controls the adjustment mechanism 14b in order that the opening degree of the through-hole H1 can be set at a degree which enables the desired number of fine bubbles to be produced stably. Thereby, it is possible to obtain the liquid mixture containing the desired number of fine bubbles.

Furthermore, in the discharge pipe 15, a large number of fine bubbles in the liquid mixture collide against the inner wall of the discharge pipe 15 because of the bent portion 15a of the discharge pipe 15. For this reason, portions of the fine bubbles can be isolated from one another. In addition, since the liquid mixture containing the large number of fine bubbles passes through the net member 15b, portions of the fine bubbles can be isolated from one another to a further extent. Accordingly, the fine bubbles can be made much finer. Through this process, the liquid mixture containing the large number of fine bubbles can be obtained stably and securely.

In the embodiment, as described above, the liquid mixture is produced by mixing the hydrogen peroxide solution into the sulfuric acid; the pressure of the produced liquid mixture is raised by use of the oxygen gas produced through the decomposition of the hydrogen peroxide solution, or by use of the vapor produced by the heat of the reaction; and the large number of fine bubbles are produced in the liquid mixture by releasing the thus-raised pressure of the liquid mixture. This raises the pressure of the liquid mixture by use of the oxygen gas produced through the decomposition of the hydrogen peroxide solution, or by use of the vapor produced by the boiling, and accordingly enables the temperature of the liquid mixture to be raised by use of the rise in the boiling point. Thereby, it is possible to enhance the cleaning performance of removing the resist film from the top surface of the substrate W. Moreover, the pressure of the liquid mixture containing the oxygen gas produced by the decomposition of the hydrogen peroxide solution or the vapor produced by the boiling is released, and the multiple fine bubbles thereby occur in the liquid mixture. The use of the liquid mixture containing the fine bubbles makes it possible to easily remove residues of the resist and the like on the substrate W. Accordingly, the cleaning performance can be enhanced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cleaning solution producing apparatus comprising:
a mixing unit configured to produce a liquid mixture by mixing a hydrogen peroxide solution into any one of an acidic liquid and an alkaline liquid, and to raise a pressure of the produced liquid mixture by use of an oxygen gas produced through decomposition of the hydrogen peroxide solution, or by use of vapor produced by heat of the reaction; and
a bubble producing unit configured to produce a plurality of fine bubbles in the liquid mixture by releasing the pressure of the liquid mixture raised by the mixing unit.

2. The cleaning solution producing apparatus of claim 1,
further comprising a heating unit configured to heat the liquid,
wherein the mixing unit mixes the hydrogen peroxide solution and the liquid heated by the heating unit.

3. The cleaning solution producing apparatus of claim 1, further comprising:
a first pressure-feeder configured to pressure-feed the liquid to the mixing unit; and
a second pressure feeder configured to pressure-feed the hydrogen peroxide solution to the mixing unit,
wherein the mixing unit is a mixing pipe configured to mix the liquid pressure-fed by the first pressure feeder and the hydrogen peroxide solution pressure-fed by the second pressure feeder.

4. The cleaning solution producing apparatus of claim 2, further comprising:
a first pressure-feeder configured to pressure-feed the liquid to the mixing unit; and
a second pressure feeder configured to pressure-feed the hydrogen peroxide solution to the mixing unit,
wherein the mixing unit is a mixing pipe configured to mix the liquid pressure-fed by the first pressure feeder and the hydrogen peroxide solution pressure-fed by the second pressure feeder.

5. The cleaning solution producing apparatus of claim 1, further comprising:
a first supply pipe configured to supply the liquid to the mixing unit; and
a second supply pipe configured to supply the hydrogen peroxide solution to the mixing unit,
wherein an inner diameter of the mixing unit is larger than that of the first supply pipe and that of the second supply pipe.

6. The cleaning solution producing apparatus of claim 2, further comprising:
a first supply pipe configured to supply the liquid to the mixing unit; and
a second supply pipe configured to supply the hydrogen peroxide solution to the mixing unit,
wherein an inner diameter of the mixing unit is larger than that of the first supply pipe and that of the second supply pipe.

7. The cleaning solution producing apparatus of claim 1, wherein the mixing unit includes an agitation structure configured to agitate the liquid and the hydrogen peroxide solution.

8. The cleaning solution producing apparatus of claim 2, wherein the mixing unit includes an agitation structure configured to agitate the liquid and the hydrogen peroxide solution.

9. The cleaning solution producing apparatus of claim 1, wherein the bubble producing unit includes:
an orifice member in which a through-hole is formed, the liquid mixture passing through the through-hole; and
an adjustment mechanism configured to adjust an opening degree of the through-hole.

10. The cleaning solution producing apparatus of claim 2, wherein the bubble producing unit includes:
an orifice member in which a through-hole is formed, the liquid mixture passing through the through-hole; and
an adjustment mechanism configured to adjust an opening degree of the through-hole.

11. The cleaning solution producing apparatus of claim 9, further comprising:
a detector configured to detect at least one of a temperature and a pressure of the liquid mixture in the mixing unit; and
a controller configured to control the opening degree of the through-hole by use of the adjustment mechanism on the basis of the at least one of the temperature and the pressure of the liquid mixture detected by the detector.

12. The cleaning solution producing apparatus of claim 1, further comprising:
a first supply pipe configured to supply the liquid to the mixing unit;
a second supply pipe configured to supply the hydrogen peroxide solution to the mixing unit; and
a discharge pipe configured to discharge the liquid mixture containing the plurality of fine bubbles which are produced by the bubble producing unit,
wherein an inner diameter of the discharge pipe is larger than that of the first supply pipe and that of the second supply pipe.

13. The cleaning solution producing apparatus of claim 2, further comprising:
a first supply pipe configured to supply the liquid to the mixing unit;
a second supply pipe configured to supply the hydrogen peroxide solution to the mixing unit; and
a discharge pipe configured to discharge the liquid mixture containing the plurality of fine bubbles which are produced by the bubble producing unit,
wherein an inner diameter of the discharge pipe is larger than that of the first supply pipe and that of the second supply pipe.

14. The cleaning solution producing apparatus of claim 1,
further comprising a discharge pipe configured to discharge the liquid mixture containing the plurality of fine bubbles produced by the bubble producing unit,
wherein the discharge pipe includes at least one bent portion which is bent at an angle not smaller than 45 degrees.

15. The cleaning solution producing apparatus of claim 2, further comprising a discharge pipe configured to discharge the liquid mixture containing the plurality of fine bubbles produced by the bubble producing unit,
wherein the discharge pipe includes at least one bent portion which is bent at an angle not smaller than 45 degrees.

16. The cleaning solution producing apparatus of claim 1, further comprising:
a discharge pipe configured to discharge the liquid mixture containing the plurality of fine bubbles produced by the bubble producing unit; and
a net member provided in a middle of the discharge pipe.

17. The cleaning solution producing apparatus of claim 1, wherein the mixing unit is made from a ceramic material.

18. A cleaning solution producing method comprising the steps of:
producing a liquid mixture by mixing a hydrogen peroxide solution into any one of an acidic liquid and an alkaline liquid, and raising a pressure of the produced liquid mixture by use of an oxygen gas produced through decomposition of the hydrogen peroxide solution, or by use of vapor produced by heat of the reaction; and
producing a plurality of fine bubbles in the liquid mixture by releasing the raised pressure of the liquid mixture.

19. A substrate cleaning apparatus comprising:
a mixing unit configured to produce a liquid mixture by mixing a hydrogen peroxide solution into any one of an acidic liquid and an alkaline liquid, and to raise a pressure of the produced liquid mixture by use of an oxygen gas produced through decomposition of the hydrogen peroxide solution, or by use of vapor produced by heat of the reaction;
a bubble producing unit configured to produce a plurality of fine bubbles in the liquid mixture by releasing the pressure of the liquid mixture raised by the mixing unit; and
a cleaning section configured to clean a substrate by use of the liquid mixture containing the plurality of fine bubbles produced by the bubble producing unit.
